(19) United States
(12) Patent Application Publication
(10) Pub. No.: US 2010/0052149 A1
(43) Pub. Date: Mar. 4, 2010

(54) SEMICONDUCTOR DEVICE AND METHOD OF MANUFACTURING THE SAME

(75) Inventors: Fujiaki Nose, Ome (JP); Hiroshi Kikuchi, Hidaka (JP); Norio Nakazato, Kashiwa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/545,465

(22) Filed: Aug. 21, 2009

(30) Foreign Application Priority Data
Sep. 4, 2008 (JP) JP2008-226971

(51) Int. Cl. H01L 23/495; H01L 21/56

(52) U.S. Cl. 257/692; 438/123; 438/124; 257/E21.502; 257/E21.506; 257/E23.031

(57) ABSTRACT

A semiconductor device includes: a die pad having a top surface; a plurality of leads arranged around the die pad; a semiconductor chip having a main surface, a back surface, and a plurality of pads formed to the main surface, and having the back surface fixedly adhered in opposing contact with the top surface of the die pad; a plurality of wires electrically connecting the plurality of pads of the semiconductor chip and the plurality of leads, respectively; and a sealing body sealing the semiconductor chip and the plurality of wires. In addition, a plurality of groove portions are formed to a chip-mounting region opposing the back surface of the semiconductor chip in the top surface of the die pad, and an adhesive for fixedly adhering the semiconductor chip to the top surface of the die pad is buried in the plurality of groove portions.

### CROSS-REFERENCE TO RELATED APPLICATION

The present application claims priority from Japanese Patent Application No. JP 2008-226971 filed on Sep. 4, 2008, the content of which is hereby incorporated by reference into this application.

### TECHNICAL FIELD OF THE INVENTION

The present invention relates to a semiconductor device and a method of manufacturing the semiconductor device. More particularly, the present invention relates to a technique effectively applied to a resin-sealed semiconductor device in which a semiconductor chip is mounted on a die pad provided to a lead frame, the semiconductor device being formed by sealing the semiconductor chip by a sealing body.

### BACKGROUND OF THE INVENTION

Package structures of semiconductor devices include a resin-sealed semiconductor device. For example, Japanese Patent Application Laid-Open Publication No. 2002-261187 (Patent Document 1) discloses a semiconductor device having a structure in which a semiconductor element (semiconductor chip) is mounted on a tab (chip-mounting portion) of a lead frame that is larger than the semiconductor element, and electrodes of the semiconductor element and leads arranged around the tab are electrically connected via wires, and the semiconductor element and wires are sealed by a resin.

In Patent Document 1, the semiconductor element is fixed to a semiconductor element fixing region of the tab via an Ag paste. In addition, a long groove in an endless shape is formed to surround the semiconductor element fixing region, and a wire connection region is provided to a surface of the tab on an outer periphery side than the groove. Wires to be electrically connected to the electrodes of the semiconductor element are connected to the wire connection region.

Patent Document 1 describes that, by forming the long groove having an endless shape surrounding the semiconductor element fixing region, contamination of the wire connection region due to exuding (bleeding phenomenon) of liquid components contained in the Ag paste can be prevented.

Also, Patent Document 1 describes that the existence of the groove increases an adhered area (bonded area) of the tab and resin (sealing resin) to provide a structure where the resin is embedded in the groove of the tab, thereby hardly exfoliating the tab from the resin.

### SUMMARY OF THE INVENTION

Performance indexes of semiconductor devices include heat dissipation property. When a semiconductor chip included in a semiconductor device is driven, heat is generated. When the temperature of the semiconductor chip itself is raised by the heat, it causes malfunction of the semiconductor chip. Therefore, semiconductor devices require an improvement of heat dissipation property for dissipating the heat generated from the semiconductor chip to the outside.

Particularly, in recent years, tendencies of down-sizing and multiple functions of semiconductor devices have seen along with an advance of fine processing technique. As to such a down-sized and multifunction semiconductor device, larger power will be supplied to the small semiconductor device. Therefore, in the point of view of improving the reliability of semiconductor devices, the heat dissipation property has been a very important performance index.

To improve the heat dissipation property of semiconductor devices, it is important to secure a heat dissipation path for efficiently transferring the heat generated in a semiconductor chip that is a heat source to the outside of the semiconductor device. As to the resin-sealed semiconductor device as mentioned above, the periphery of the semiconductor chip is sealed by a resin material having a lower heat conductivity than metal, so that paths of transferring heat to the outside through wires bonded to the pad of the semiconductor chip and leads to which the other ends of the wires are bonded play the role as the main heat dissipation pass.

However, as the wires and leads have been thinned with down-sizing and multiple functions of semiconductor devices, heat may not be sufficiently dissipated by only the heat dissipation paths through wires.

In such a situation, efforts for facilitating the chip-mounting portion to which the semiconductor chip is mounted as the heat dissipation path have been made. For example, as described in Patent Document 1, the Ag paste used as an adhesive for fixing the semiconductor chip to the chip-mounting portion is a paste in which fine particles of Ag (silver) having a high heat conductivity are contained to a resin such as epoxy resin, and when the paste is used as an adhesive, the heat conductivity can be improved more than the case of using a resin adhesive in which Ag particles are not added.

However, since the Ag paste is required to function as an adhesive, the amount of Ag particles to be contained in the paste cannot be excessively increased, and as a result, the heat dissipation path through the Ag particles contained in the resin is disrupted by the resin, and thus a sufficient improvement of heat dissipation property has not been achieved yet.

Meanwhile, a technique of forming a groove to a surface of the chip-mounting portion (around the semiconductor element fixing region) is described in above-mentioned Patent Document 1, and the groove is provided in the point of view of preventing contamination of the wire connection region due to the bleeding phenomenon or in the point of view of preventing exfoliation of the sealing resin and the chip-mounting portion, but Patent Document 1 fails to describe anything in the point of view of heat dissipation property of the semiconductor device.

The present invention has been made in the point of view of the above-mentioned problems, and a preferred aim of the present invention is to provide a technique capable of improving the heat dissipation property of a semiconductor device.

The above and other preferred aims and novel characteristics of the present invention will be apparent from the description of the present specification and the accompanying drawings.

The typical ones of the inventions disclosed in the present application will be briefly described as follows.

That is, a semiconductor device according to an embodiment of the present invention includes: a chip-mounting portion having a first main surface and a first back surface positioned opposite to the first main surface; a plurality of suspending leads supporting the chip-mounting portion; a plurality of leads arranged around the chip-mounting portion; a semiconductor chip having a second main surface, a second back surface positioned opposite to the second main surface, and a plurality of pads formed to the second main surface, the semiconductor chip being fixedly adhered on the first main surface so as to have the second back surface being in opposing contact with the first main surface of the chip-mounting portion; a plurality of wires electrically connecting the plurality of pads of the semiconductor chip and the plurality of leads; and a sealing body sealing the semiconductor chip and the plurality of wires. In addition, in the first main surface of the chip-mounting portion, a plurality of first groove portions are formed in a region opposing the second back surface of the semiconductor chip, and an adhesive for adhering the semiconductor chip onto the first main surface of the chip-mounting portion is buried inside the plurality of first groove portions.

The effects obtained by typical aspects of the present invention will be briefly described below.

That is, the heat dissipation property of a semiconductor device can be improved.

### BRIEF DESCRIPTIONS OF THE DRAWINGS

FIG. 1 is a plan view illustrating a top surface side of a semiconductor device according to an embodiment of the present invention;

FIG. 2 is a plan view illustrating a bottom surface side of the semiconductor device illustrated in FIG. 1;

FIG. 3 is a cross-sectional view taken along the line A-A illustrated in FIG. 1;

FIG. 4 is a plan view illustrating a planar structure inside a sealing body of the semiconductor device illustrated in FIG. 1;

FIG. 5 is an enlarged plan view illustrating a periphery of a die pad illustrated in FIG. 4 in an enlarged manner;

FIG. 6 is an enlarged plan view of an essential part illustrated with eliminating a semiconductor chip and wires illustrated in FIG. 5;

FIG. 7 is an enlarged cross-sectional view taken along the line B-B illustrated in FIG. 5;

FIG. 8 is an enlarged plan view illustrating a part of a lead frame used in manufacture of the semiconductor device according to the embodiment of the present invention in an enlarged manner, the part being corresponded to one piece of semiconductor device;

FIG. 9 is a cross-sectional view taken along the line C-C illustrated in FIG. 8, and also is an enlarged cross-sectional view illustrating a periphery of the die pad in an enlarged manner;

FIG. 10 is a plan view illustrating a state of having an adhesive for adhering the semiconductor chip applied to the lead frame illustrated in FIG. 8, and also is an enlarged plan view illustrating the periphery of the die pad in a further enlarged manner;

FIG. 11 is an enlarged cross-sectional view taken along the line C-C illustrated in FIG. 10;

FIG. 12 is an enlarged plan view illustrating a state of having the semiconductor chip arranged onto the die pad illustrated in FIG. 10;

FIG. 13 is an enlarged cross-sectional view taken along the line C-C illustrated in FIG. 12;

FIG. 14 is an enlarged plan view illustrating a state of pressing the semiconductor chip illustrated in FIG. 12 toward the die pad;

FIG. 15 is an enlarged cross-sectional view taken along the line D-D illustrated in FIG. 14;

FIG. 16 is an enlarged plan view illustrating a state of electrically connecting the pad of the semiconductor chip illustrated in FIG. 14 and the leads via wires;

FIG. 17 is an enlarged cross-sectional view taken along the line C-C illustrated in FIG. 16;

FIG. 18 is a cross-sectional view of a semiconductor device according to another embodiment of the present invention;

FIG. 19 is an enlarged cross-sectional view illustrating a periphery of an adhering portion of a die pad and a semiconductor chip illustrated in FIG. 18 in an enlarged manner;

FIG. 20 is a plan view illustrating a top surface side of a semiconductor device according to still another embodiment of the present invention;

FIG. 21 is a plan view illustrating a bottom surface side of the semiconductor device illustrated in FIG. 20;

FIG. 22 is a plan view illustrating one side surface side of the semiconductor device illustrated in FIG. 20;

FIG. 23 is a cross-sectional view taken along the line E-E illustrated in FIG. 20; and

FIG. 24 is a cross-sectional view taken along the line E-E illustrated in FIG. 20, and illustrating a modification example of the semiconductor device illustrated in FIG. 23.

### DESCRIPTIONS OF THE PREFERRED EMBODIMENTS

In the embodiments described below, components having the same function are denoted by the same reference symbols throughout the drawings for describing the embodiment, and the repetitive description thereof will be basically omitted. Also, in all drawings for describing the embodiments, hatching or pattern is used even in a plan view so as to make the configuration of respective components easy to understand. Hereinafter, embodiments of the present invention will be described in detail with reference to the accompanying drawings.

### First Embodiment

### Structure of Semiconductor Device

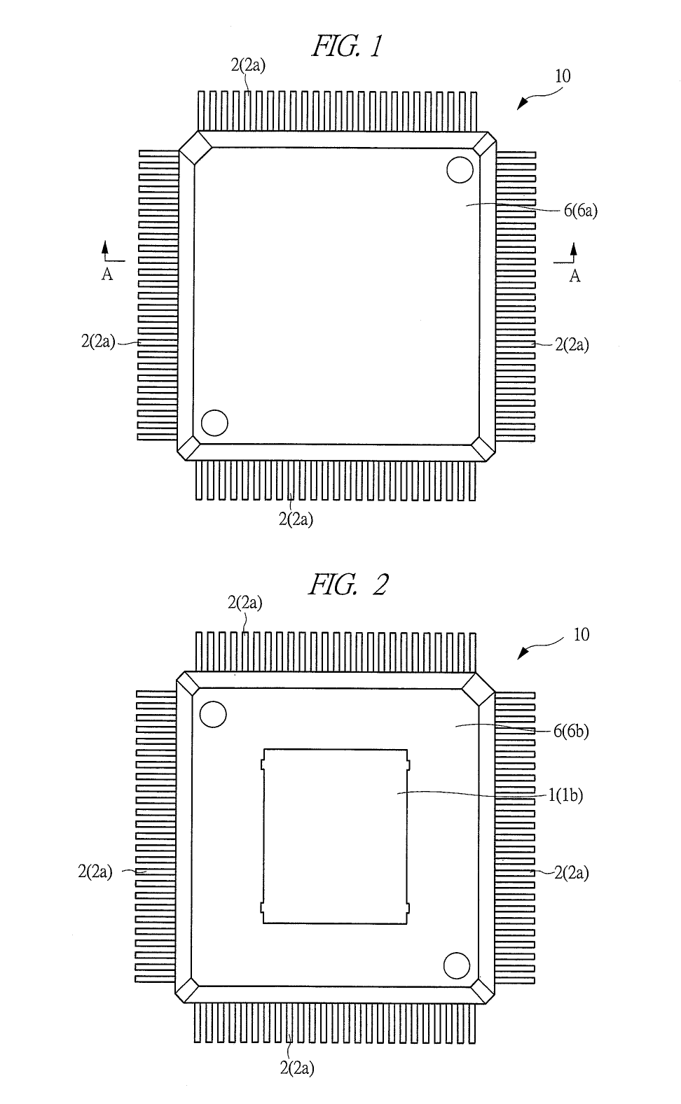

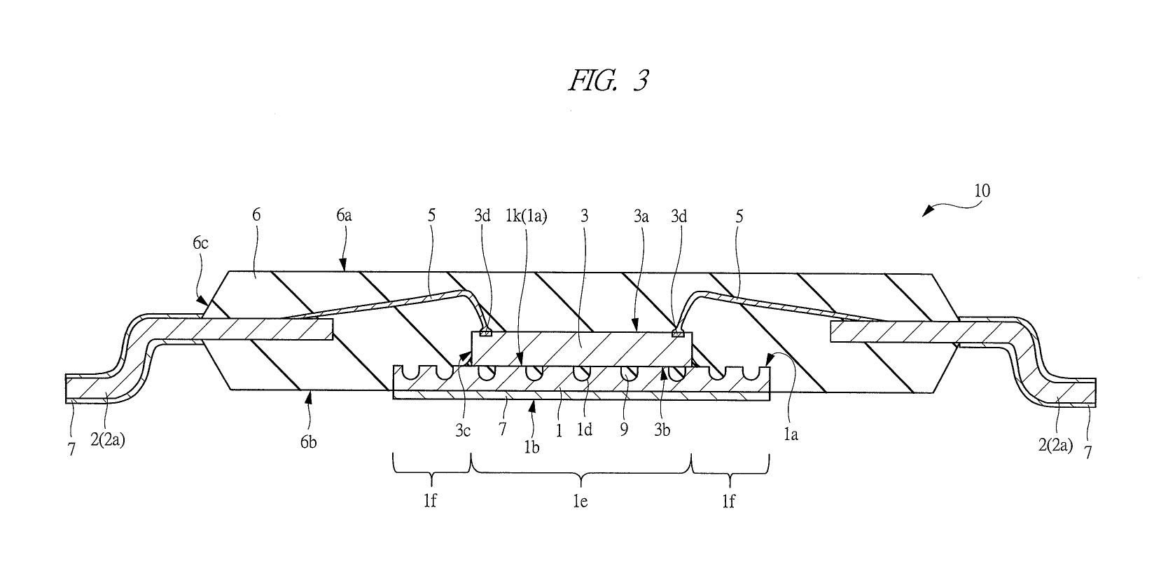

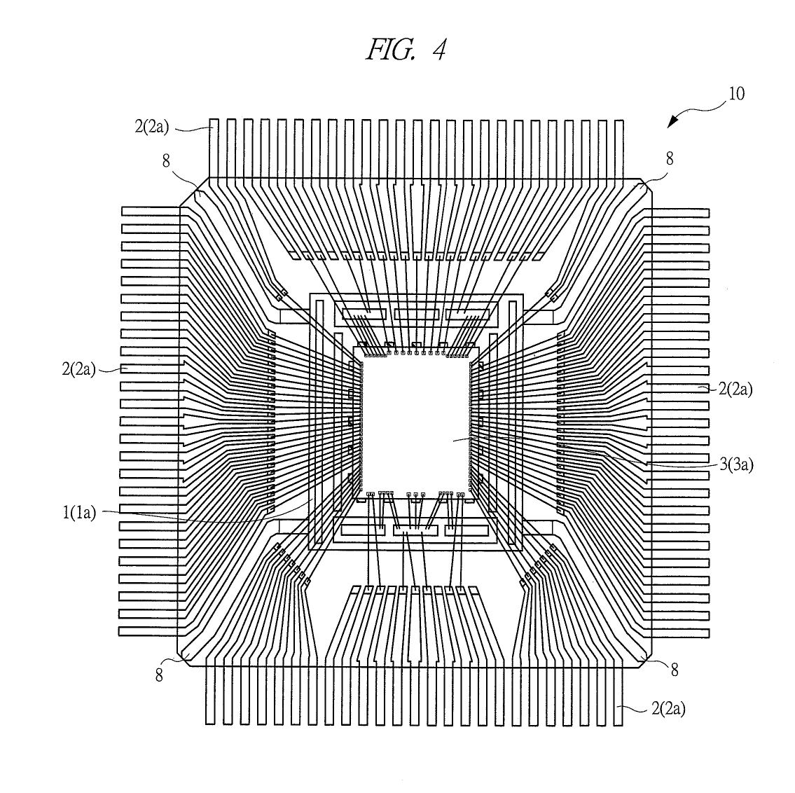

First, a structure of a semiconductor device according to a first embodiment will be described with reference to FIGS. 1 to 5. FIG. 1 is a plan view illustrating a top surface side of a semiconductor device according to the first embodiment, FIG. 2 is a plan view illustrating a bottom surface side of the semiconductor device illustrated in FIG. 1, and FIG. 3 is a cross-sectional view taken along the line A-A illustrated in FIG. 1. In addition, FIG. 4 is a plan view illustrating a planar structure inside a sealing body of the semiconductor device illustrated in FIG. 1, and FIG. 5 is an enlarged plan view illustrating a periphery of a die pad illustrated in FIG. 4 in an enlarged manner. Note that the plan views of FIGS. 4 and 5 illustrate an inner structure with making the sealing body transparent to see the configuration inside.

The semiconductor device according to the first embodiment is a semiconductor package of a lead frame type in which a semiconductor chip is mounted on a die pad that is a chip-mounting portion of a lead frame. In the first embodiment, as an example of such a semiconductor device, a QFP (quad flat package) 10 that is a semiconductor device of the lead frame type as illustrated in FIG. 1 is picked up and described.

In FIGS. 1 to 5, the QFP 10 of the first embodiment includes: a die pad (chip-mounting portion) 1; a plurality of leads 2 arranged around the die pad 1; a suspending lead 8 supporting the die pad 1; a semiconductor chip 3 mounted on a top surface (first main surface) 1a of the die pad 1; a plurality of wires 5 electrically connecting the semiconductor chip 3 and the plurality of leads 2, respectively; and a sealing body 6 sealing the semiconductor chip 3 and the plurality of wires 5. The QFP 10 has a rectangle shape in plan view of a surface crossing a thickness direction, and the plurality of leads 2 are led out from each side of the rectangle.

The die pad 1 has a top surface (first main surface) 1a, and a bottom surface (first back surface) 1b on the opposite side of the top surface 1a. The bottom surface 1b of the die pad 1 is exposed from a bottom surface 6b side of the sealing body 6, and an outer plating layer (metal layer) 7 is formed on a surface of the bottom surface 1b. Note that, in FIGS. 1 and 2, while symbols of the die pad 1 and the leads 2 are denoted to show positions of the die pad 1 and the leads 2, surfaces of the die pad 1 and the leads 2 exposed from the sealing body 6 are covered with the outer plating layer 7. The outer plating layer 7 is formed, for example, to improve bonding property upon mounting the QFP 10 to a mounting board. Therefore, the outer plating layer 7 is composed of a bonding material used for mounting a semiconductor device to a mounting board, for example, a metal material such as solder.

Also, a planar shape (planar shape of a surface crossing the thickness direction) of the die pad 1 is rectangular in the first embodiment. Further, an area of the top surface 1a of the die pad 1 is larger than that of a second back surface 3b of the semiconductor chip 3 to be mounted on the top surface 1a, and the back surface 3b of the semiconductor chip 3 is covered by the top surface 1a of the die pad 1.

Still further, a plurality of the suspending leads 8 are arranged around the die pad 1, and the die pad 1 is supported by the plurality of suspending leads 8. More specifically, the suspending lead 8 is a supporting part by means of joining the die pad 1 and a supporting frame of the lead frame in a manufacturing process of the QFP 10.

The suspending lead 8 is formed with being integrated with the die pad 1, and one end of the suspending lead 8 is connected to an outer edge of the die pad 1 (in FIG. 4, two lines in each of two sides opposing each other among the four sides which the die pad 1 has) to extend toward an outer edge of the QFP 10 (in FIG. 4, a direction to the four corners which the QFP 10 has). In addition, the suspending lead 8 has a bended portion in the midst thereof to be offset (downset) so that the die pad 1 is positioned at the lowest position. Thereby, in the first embodiment, the suspending lead 8 is not exposed to the bottom surface (the bottom surface 6b of the sealing body 6) side of the QFP 10 and is sealed by the sealing body 6.

The plurality of leads 2 arranged around the die pad 1 are external connection terminals of the QFP 10, respectively, and inner leads 2b to be sealed inside the sealing body 6 and outer leads 2a to be led out from the sealing body 6 are integrally formed. The plurality of leads 2 are arranged in four directions along each side composing the outer edge of the die pad 1, respectively. In the first embodiment, a 100-pin type having 25 lines of the leads 2 arranged along each side is exemplified.

The outer lead 2a is exposed from a side surface 6c side of the sealing body 6, and the outer plating layer 7 is formed on a surface of the exposed outer lead 2a. On the other hand, a top surface of the inner lead 2b is a bonding surface for bonding the wire 5, to which a plating layer (not illustrated) formed by laminating single or multiple metal layers is formed to improve the bonding strength between the wire 5 and the lead 2 or to reduce the electric resistance at the bonding surface between the wire 5 and the lead 2.

The above-described die pad 1, the suspending lead 8, and the plurality of leads 2 compose a part of the lead frame to be used in the manufacture stage of the QFP 10. That is, the QFP 10 is a semiconductor device of the lead frame type in which the semiconductor chip 3 is mounted to the die pad 1 that is a chip-mounting portion of the lead frame. Therefore, the die pad 1, the suspending lead 8, and the plurality of leads 2 are formed of the same metal material, respectively. For example, in the first embodiment, the die pad 1, the suspending lead 8, and the plurality of leads 2 are formed of Cu (copper).

The semiconductor chip 3 is fixedly adhered onto the top surface 1a of the die pad 1. The semiconductor chip 3 has a main surface (second main surface) 3a, the back surface (second back surface) 3b positioned on the opposite side of the main surface 3a, and a side surface 3c positioned between the main surface 3a and the back surface 3b. The back surface 3b is provided to be in opposing contact with the top surface 1a of the die pad 1.

A plurality of groove portions (first groove portions) 1d are formed to the top surface 1a of the die pad 1, and an adhesive 9 for fixedly adhering the semiconductor chip 3 is buried inside the plurality of groove portions 1d. The semiconductor chip 3 is fixedly adhered onto the top surface 1a of the die pad 1 by the adhesive force of the adhesive 9, and details of that will be described later.

The semiconductor chip 3 has the main surface (second main surface) 3a and the back surface (second back surface) 3b, and planar shapes of the main surface 3a and the back surface 3b which are surfaces crossing the thickness direction are rectangle. Also, the semiconductor chip 3 is formed with using a semiconductor material such as silicon (Si) as its base material.

A plurality of semiconductor elements such as diodes or transistors are formed to the main surface 3a of the semiconductor chip 3, and an integrated circuit electrically connecting the semiconductor elements is formed. Also, a pad (chip terminal) 3d that is an external terminal of the semiconductor chip 3 to be electrically connected to the semiconductor elements and the integrated circuit is formed to the main surface 3a. A plurality of the pads 3d are arranged to each side along the outer circumference of the main surface 3a of the semiconductor chip 3.

In addition, a part of the pad 3d is electrically connected to the inner lead 2b via the wire 5 that is a metal thin wire such as gold wire, and the other part is electrically connected to a wire bonding portion 1c formed to the top surface 1a of the die pad 1 via the wire 5. The QFP 10 utilizes the die pad 1 as an external connection terminal for supplying a reference potential or a power supply potential by electrically connecting the wire bonding portion 1c formed to the top surface 1a of the die pad 1 and the pad 3d.

Also, the semiconductor chip 3 and the plurality of wires 5 are sealed by the sealing body 6. By sealing the semiconductor chip 3 and the plurality of wires 5 by the sealing body 6, the semiconductor chip 3 and the plurality of wires 5 can be protected. In the first embodiment, as a material of the sealing body 6, a sealing resin in which an additive such as a filler, a curing agent, or a coloring agent are added is used with taking an epoxy resin that is a thermosetting resin as the base material.

<Study on Heat Dissipation Property of the Semiconductor Device>

Here, the heat dissipation property of the QFP 10 will be described. In the QFP 10, it is necessary to dissipate the heat generated upon driving the semiconductor chip 3 to the outside to normally operate the semiconductor chip 3. While a heat dissipation path continuously connected to the outside of the QFP 10 from the semiconductor chip 3 is necessary to dissipate the heat to the outside, the heat dissipation path is preferable to be formed with using a material having a higher heat conductivity than that of the sealing body 6 to efficiently perform heat dissipation.

A path to be led out to the outside of the QFP 10 from the pad 3d of the semiconductor chip 3 through the wire 5, the inner lead 2b, the outer lead 2a, and the outer plating layer 7 is connected by a metal material having a higher heat conductivity than that of the material composing the sealing body 6 such as an epoxy-based resin material. Thereby, the path composes a first heat dissipation path of the QFP 10.

Also, as described above, the pad 3d is also connected to the die pad 1 via the wire 5, and the die pad 1 is exposed from the bottom surface 6b side of the sealing body 6. And, a path to be led out to the outside of the QFP 10 from the pad 3d through the wire 5, the die pad 1, and the outer plating layer 7 is connected by a metal material having a higher heat conductivity than that of the material composing the sealing body 6 such as an epoxy-based resin material. Thereby, the path composes a second heat dissipation path of the QFP 10.

However, in recent years, down-sizing and multiple functions are required for semiconductor devices such as the QFP 10 along with an advance of fine processing technique. Therefore, further higher heat dissipation property is required along with an increase of power supplied to the QFP 10, and thus there may be a case of insufficient heat dissipation by the use of only the first and second heat dissipation path. To explain in more detail, the wire 5 which is a metal thin wire intermediates in the first and second heat dissipation paths. Meanwhile, since the heat dissipation efficiency is improved in proportion to the heat transferring area, there is a limitation in using only the heat dissipation paths being intermediated by the wire 5.

Accordingly, in the QFP 10, it is structured such that the back surface 3b of the semiconductor chip 3 and the top surface 1a of the die pad 1 are contacted with each other as illustrated in FIG. 3, so that a third heat dissipation path which is led out to the outside of the QFP 10 from the back surface 3b of the semiconductor chip 3 through the die pad 1 and the outer plating layer 7 is provided in the QFP 10. More specifically, the back surface 3b of the semiconductor chip 3 contacts with a contact portion 1k arranged in a chip-mounting region 1e in the top surface 1a of the die pad 1.

The third heat dissipation path does not have an adhesive or the like intermediated in the path because it is formed by contacting the back surface 3b of the semiconductor chip 3 and the top surface 1a of the die pad 1. That is, the third heat dissipation path is a heat dissipation path formed of a metal material having a higher heat conductivity than those of resin materials. Also, since the back surface 3b of the semiconductor chip 3 and the top surface 1a of the die pad 1 are in opposing contact, a very large heat transferring area can be ensured as compared with the first and second heat dissipation paths through the wire 5. Thereby, the heat dissipation property can be drastically improved as compared with the semiconductor device dissipating heat by the use of only the first and second heat dissipation paths.

Further, the QFP 10 also has the first and second heat dissipation paths in addition to the third heat dissipation path. Thereby, the heat dissipation property can be further improved as compared with the case of dissipating heat by the use of only the third heat dissipation path.

Note that, as a modification example of the QFP 10, it can be a structure in which the bottom surface 1b of the die pad 1 is not exposed to the bottom surface 6b side of the sealing body 6, that is, a structure in which the die pad 1 is sealed by the sealing body 6. Also in this case, by contacting the back surface 3b of the semiconductor chip 3 and the top surface 1a of the die pad 1 opposing each other, a fourth heat dissipation path led out to the outside of the QFP 10 from the back surface 3b of the semiconductor chip 3 through the die pad 1 and the suspending lead 8 is formed, and thus the heat dissipation property is improved as compared with the structure in which the semiconductor chip 3 is not contacted with the die pad 1. Note that, if the bottom surface 1b of the die pad 1 is exposed to the bottom surface 6b side of the sealing body 6 as the QFP 10, a very large heat transferring area can be ensured as described above, and thus the bottom surface 1b of the die pad 1 is preferable to be exposed to the bottom surface 6b side of the sealing body 6 in the point of view of improving the heat dissipation property.

Also, as another modification example of the QFP 10, it can be a structure in which an area of the top surface 1a of the die pad 1 is smaller than an area of the back surface 3b of the semiconductor chip 3. However, since it is preferable to take a contact area of the top surface 1a of the die pad 1 and the back surface 3b of the semiconductor chip 3 as large as possible from the point of view of improving the heat dissipation property, the area of the top surface 1a of the die pad 1 is preferable to be larger or equal to the area of the back surface 3b of the semiconductor chip 3.

<Study on Adhesive Strength for Fixedly Adhering the Semiconductor Chip>

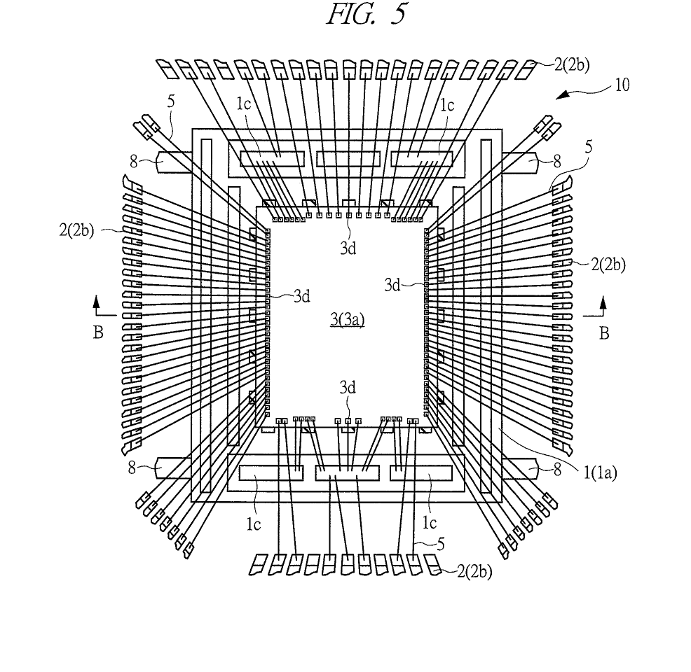

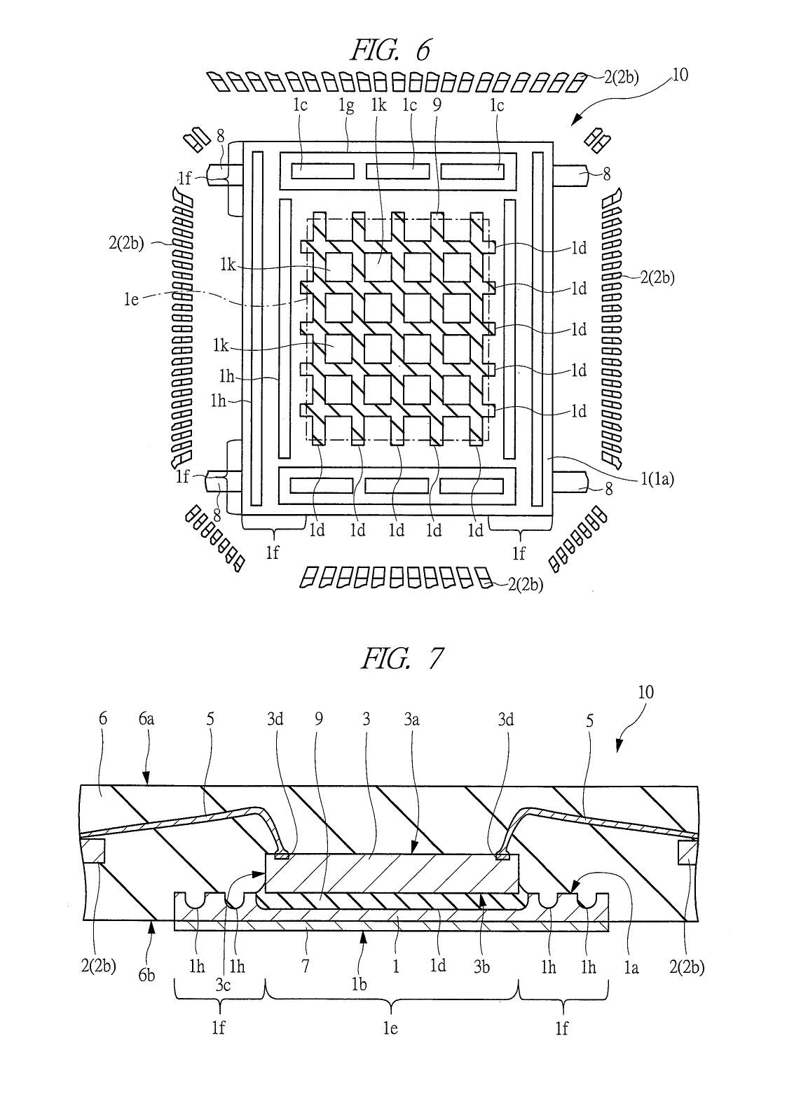

In the QFP 10 according to the first embodiment, while the heat dissipation property is drastically improved by contacting the back surface 3b of the semiconductor chip 3 and the top surface 1a of the die pad 1 opposing each other, new problems arise to achieve the opposing contact. That is, it is necessary to ensure an adhesive strength required for fixedly adhering the semiconductor chip 3 onto the top surface 1a of the die pad 1. FIG. 6 is an enlarged plan view of an essential part illustrated with eliminating the semiconductor chip and wires illustrated in FIG. 5, and FIG. 7 is an enlarged cross-sectional view taken along the line B-B illustrated in FIG. 5.

Accordingly, it is structured in the first embodiment such that, in the top surface 1a of the die pad 1, the plurality of groove portions (first groove portions) 1d are formed in the chip-mounting region (first region) 1e opposing the back surface 3b of the semiconductor chip 3, and the adhesive 9 for fixedly adhering the semiconductor chip 3 is buried in the plurality of groove portions 1d. In this manner, by the adhesive 9 buried in the groove portion 1d, the back surface 3b of the semiconductor chip 3 can be in opposing contact with the top surface 1a of the die pad 1 as well as fixedly adhering the semiconductor chip 3 onto the die pad 1. More specifically, the back surface 3b of the semiconductor chip 3 contacts with the contact portion 1k arranged in the chip-mounting region 1e in the top surface 1a of the die pad 1.

While an example of an arrangement of the groove portions 1d in which the five groove portions 1d in each of the row direction and the column direction are formed in matrix of crossing each other in FIG. 6, the arrangement, the number, or the shape of the groove portion 1d is not limited to this. Meanwhile, in the point of view of improvement of the heat dissipation property, since it is preferable to take the contact area of the back surface 3b of the semiconductor chip 3 and the top surface 1a of the die pad 1 as large as possible, the area of the region in which the groove portions 1d are formed is preferable to be as small as possible in a range capable of ensuring a required adhesive strength.

Also, to make the burying in the groove portion 1d easy, a method of fixedly adhering the adhesive 9 by curing after burying the paste-like adhesive is preferable. As the material, resin adhesive materials generally used for die-bonding of semiconductor chips can be used. For example, in the first embodiment, a thermosetting resin in which an additive such as a curing agent is added to an epoxy resin is used. Also, a conductive adhesive called Ag paste in which a metal filler (metal particles) such as Ag (silver) is added to a thermosetting region can be used. Meanwhile, in the QFP 10 according to the present embodiment, the metal filler for improving conductivity or thermal conductivity is preferable not to be contained in the adhesive 9. Since the semiconductor chip 3 and the die pad 1 are in opposing contact in the QFP 10, the semiconductor chip 3 is pressed toward the die pad 1 side in a die-bonding step (details will be described later). At this time, if metal filler particles of such as Ag remain in regions other than the groove portion 1d, the metal filler particles can cause inhibition of the opposing contact of the semiconductor chip 3 and the die pad 1. Also, according to the first embodiment, the heat dissipation property can be improved without mixing an expensive precious metal such as Ag in the adhesive 9, and thus the manufacture cost of the QFP 10 can be reduced.

Further, the QFP 10 has a structure as described below in the point of view of taking the contact area of the back surface 3b of the semiconductor chip 3 and the top surface 1a of the die pad 1 as large as possible and improving the adhesive strength.

That is, the area of the top surface 1a of the die pad 1 is larger than the area of the back surface 3b of the semiconductor chip 3, and the die pad 1 has a chip periphery region (second region) if around the chip-mounting region 1e illustrated in FIG. 6. The chip periphery region 1f is provided to surround around the chip-mounting region 1e. And, the groove portion 1d is formed to extend from the chip-mounting region 1e to the chip periphery region 1f in the top surface 1a of the die pad 1.

By forming the groove portion 1d extending from the chip-mounting region 1e to the chip periphery region 1f, the groove portion 1d is formed to continuously connect to a region not opposing the semiconductor chip 3 as illustrated in FIG. 7. Thereby, upon burying the adhesive 9 in the groove portion 1d, even if the paste-like adhesive 9 is arranged at arbitral positions in the chip-mounting region 1e, when the semiconductor chip 3 is pressed toward the die pad 1, the excessive part of the adhesive 9 is pushed out from the chip-mounting region 1e toward the chip periphery region 1f. As a result, the top surface 1a of the die pad 1 and the back surface 3b of the semiconductor chip 3 can be easily contacted with opposing each other. Also, in the point of view of making the excessive part of the adhesive 9 easy to be pushed out toward the chip periphery region 1f, it is preferable to form each of the groove portions 1d in a belt-like shape as illustrated in FIG. 6, and the two ends of the groove portion 1d are arranged within the chip periphery region 1f, respectively.

In addition, in the die-bonding step, when the volume of the paste-like adhesive 9 to be applied is larger than the total volume of the same inside the groove portion 1d, a part of the adhesive 9 protrudes from the two ends of the groove portion 1d as illustrated in FIG. 7 as the excessive part of the adhesive 9 is pushed out from the chip-mounting region 1e toward the chip periphery region 1f side. The part of the adhesive 9 protruded from the two ends of the groove portion 1d is adhered also onto the side surface 3c of the semiconductor chip 3 as illustrated in FIG. 7. That is, the adhesive 9 is adhered onto both the back surface 3b and the side surface 3c of the semiconductor chip 3. In other words, the semiconductor chip 3 is fixedly adhered with having a plurality of crossing surfaces (back surface 3b and side surface 3c) adhered with the adhesive 9.

In the point of view of the adhesive strength of adhering the semiconductor chip 3 onto the die pad 1, adhering the adhesive 9 onto the plurality of crossing surfaces of the semiconductor chip 3 improves the adhesive strength more than adhering onto one surface thereof. That is, in the QFP 10, the adhesive strength of adhering the semiconductor chip 3 onto the die pad 1 can be improved by adhering the adhesive 9 onto both the back surface 3b and the side surface 3c of the semiconductor chip 3. In this manner, by attaching the adhesive 9 to the side surface 3c, the adhesive strength can be improved, so that the contact area of the back surface 3b of the semiconductor chip 3 and the top surface 1a of the die pad 1 in the chip-mounting region 1e can be further enlarged as compared with the case of simply adhering the adhesive 9 onto only the back surface 3b.

<Description of Second Groove Formed in the Chip Periphery Region>

In FIGS. 6 and 7, a groove portion (second groove portion) 1g having an endless shape formed to surround round the wire bonding portion 1c, and a groove portion (second groove portion) 1h having a belt-like shape formed to extend in the chip periphery region 1f along the outer edge side of the die pad 1 are formed to the top surface 1a of the die pad 1.

These groove portions 1g and 1h are first formed for protecting the wire bonding portion 1c on the die pad 1 from exuding (bleeding phenomenon) of liquid components contained in the adhesive 9. Second, the groove portions 1g and 1h are formed for preventing exfoliation between the die pad 1 and the sealing body 6 by burying the sealing body 6 in the groove portions 1g and 1h to embed the sealing body 6 into the groove portions 1g and 1h. For those reasons, the groove portions 1g and 1h are formed to be separated from the above-described first groove portion 1d, and they are formed only in the chip periphery portion 1f.

Both the groove portions 1g and 1h and the groove portion 1d are formed by etching. Therefore, the groove portions 1d, 1g, and 1h can be formed at the same time, and thus the groove portion 1d can be formed without particularly adding a manufacturing step.

Note that, while various modification examples are present for the shapes of the groove portions 1g and 1h, descriptions thereof will be omitted in the first embodiment because the above-described Patent Document 1 describes them in detail.

Also, it is needless to say that the die pad 1 not having the groove portions 1g and 1h illustrated in FIGS. 6 and 7 can be also used as the modification example of the QFP 10. For example, in the case of using the structure in which the area of the top surface 1a of the die pad 1 is smaller than the area of the back surface 3b of the semiconductor chip 3 described above as another modification example of the QFP 10 in the section <Study on Heat Dissipation Property of the Semiconductor Device>, the die pad 1 not having the groove portions 1g and 1h is used. In this case, the space for forming the groove portions 1g and 1h can be eliminated, thereby achieving further down-sizing.

Meanwhile, in the case of using the structure in which the area of the top surface 1a of the die pad 1 is smaller than the area of the back surface 3b of the semiconductor chip 3, it is difficult to form the groove portion 1d extending from the chip-mounting region 1e to the chip periphery region 1f as the QFP 10, and thus it is preferable to form the groove portion 1d continuously connected to the side surface of the die pad 1. In this manner, in the die-bonding process, the excessive adhesive 9 is pushed out toward the side surface of the die pad 1, so that it becomes easier to contact the top surface 1a of the die pad 1 and the back surface 3b of the semiconductor chip 3 opposed to each other.

<Method of Manufacturing the Semiconductor Device>

Next, a method of manufacturing the QFP 10 illustrated in FIGS. 1 to 7 will be described.

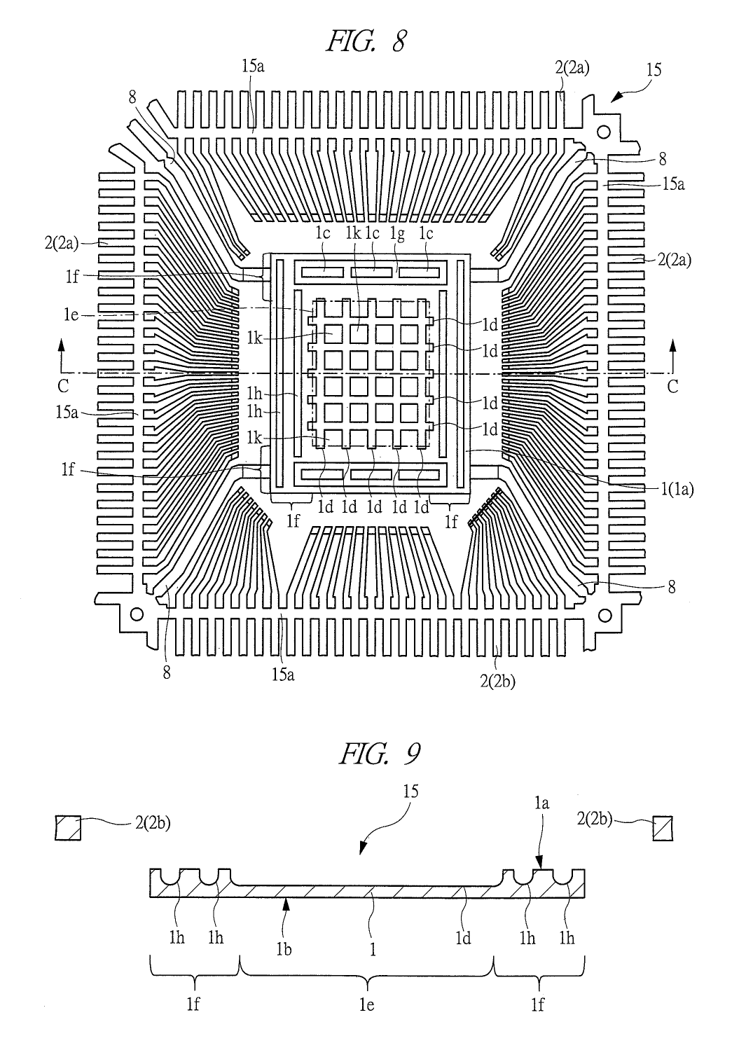

(a) First, a lead frame 15 illustrated in FIGS. 8 and 9 is prepared (lead frame preparation step). FIG. 8 is an enlarged plan view illustrating a part of the lead frame used in manufacture of the semiconductor device according to the first embodiment in an enlarged manner, the part being corresponded to one piece of the semiconductor device, and FIG. 9 is a cross-sectional view taken along the line C-C illustrated in FIG. 8, also an enlarged cross-sectional view illustrating a periphery of the die pad in an enlarged manner.

In the lead frame 15 prepared in this step, a plurality of the unit lead frames coupled in its plan view by a supporting frame (frame body; not illustrated) of the lead frame 15 can be used, the unit lead frame being corresponded to one piece of semiconductor device illustrated in FIG. 8. Further, the die pad 1, the plurality of leads 2, and the plurality of suspending leads 8 formed on the lead frame 15 are coupled via the supporting frame of the lead frame, a tie bar 15a, and the like, respectively.

The lead frame 15 illustrated in FIGS. 8 and 9 is obtained by the following way, for example. First, a thin plate of iron-based (e.g., iron-nickel alloy etc.) or copper-based (e.g., copper or a member in which a plating layer of nickel or the like is formed on the surface of copper) is prepared and is subject to an etching processing or a pressing processing to form the die pad 1, the plurality of leads 2, the plurality of suspending leads 8, the tie bar 15a, and so forth in a predetermined pattern.

Next, as a groove portion formation step, the groove portions 1d, 1g, and 1h are simultaneously formed on the top surface 1a side of the die pad 1 by an etching processing. In this step, with using a technique called half-etching processing technique, the groove portions 1d, 1g, and 1h are formed by performing the etching processing from the top surface 1a side of the die pad 1 to a substantially half depth of the die pad 1.

Next, as an offsetting step, the position of the die pad 1 is offset (downset, in the first embodiment). The offsetting is performed by providing a bending work to a predetermined position of the suspending lead 8 with using a punch and a die.

When the offsetting step is finished, as illustrated in FIGS. 8 and 9, the lead frame 15 having the die pad 1, the plurality of suspending leads 8 supporting the die pad 1, the plurality of leads 2 arranged around the die pad 1, and the supporting frame integrally formed with the plurality of suspending leads 8 and the plurality of leads 2 the die pad 1, the plurality of suspending leads 8 supporting the die pad 1, and the plurality of leads 2 arranged around the die pad 1 is obtained.

(b) Next, the semiconductor chip 3 is prepared and mounted onto the top surface 1a of the die pad 1 (die-bonding process). This step includes the following steps.

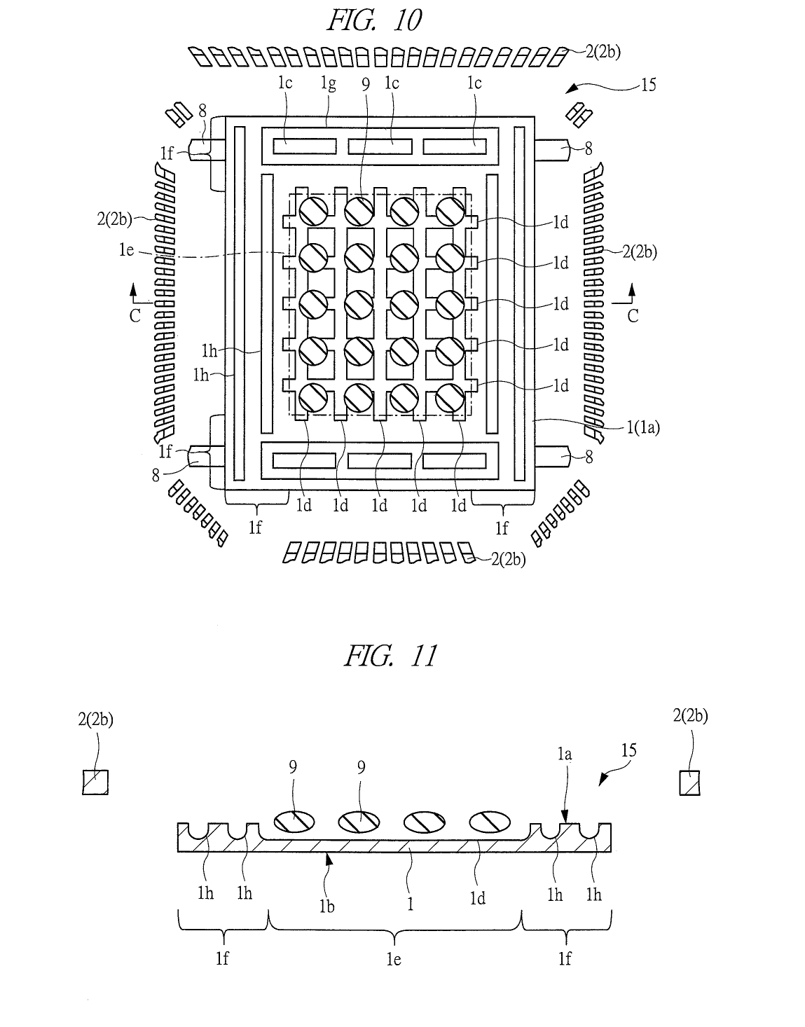

(b1) First, as illustrated in FIGS. 10 and 11, the adhesive 9 is applied to the top surface 1a of the die pad 1 (adhesive application step). FIG. 10 is a plan view illustrating a state of applying the adhesive for adhering the semiconductor chip to the lead frame illustrated in FIG. 8, and also is an enlarged plan view illustrating the periphery of the die pad in a further enlarged manner, and FIG. 11 is an enlarged cross-sectional view taken along the line C-C illustrated in FIG. 10.

In this step, the adhesive 9 for fixing the semiconductor chip 3 and the die pad 1 is provided on each of the top surfaces 1a of the die pad 1 of the lead frame 15. Here, the adhesive 9 used in the first embodiment is made of a paste-like thermosetting resin. Therefore, the paste-like adhesive 9 is provided on the top surface 1a of the lead frame 15 (more specifically, on the chip-mounting region 1e) by application. Also, since the shape of the adhesive 9 is deformed in a semiconductor chip pressing step to be described later, the adhesive 9 can be arranged at a substantially constant distance in the chip-mounting region 1e in the stage of this step, and a high arrangement precision is not required. Therefore, as a method of applying the adhesive 9, a method generally used for applying a paste-like adhesive (e.g., dispense method) or the like can be used.

Here, as described above, when the applied volume of the paste-like adhesive 9 is larger than the total volume of the adhesive 9 inside the groove portion 1d, the adhesive 9 can be adhered also onto the side surface 3c of the semiconductor chip 3 as illustrated in FIG. 7. Therefore, in this process, it is preferable to apply a larger amount of the adhesive 9 than the total volume of the adhesive 9 inside the groove portion 1d beforehand.

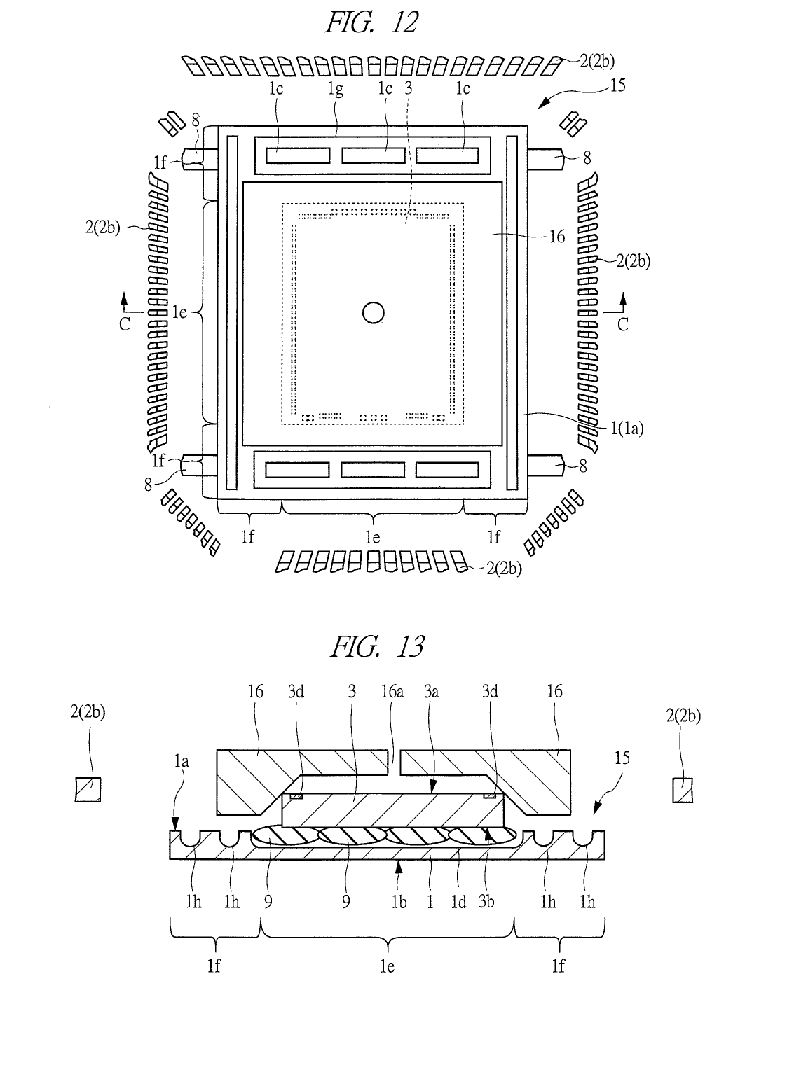

(b2) Next, as illustrated in FIGS. 12 and 13, the semiconductor chip 3 is prepared and arranged on the chip-mounting region 1e of the die pad 1 to which the adhesive 9 is applied (semiconductor chip arrangement step). FIG. 12 is an enlarged plan view illustrating a state of having the semiconductor chip arranged onto the die pad illustrated in FIG. 10, and FIG. 13 is an enlarged cross-sectional view taken along the line C-C illustrated in FIG. 12.

In this step, the semiconductor chip 3 is transferred to a position above the chip-mounting region 1e with using a collet 16 which is a sucking tool, thereby arranging the semiconductor chip 3. In FIGS. 12 and 13, an example called “pyramid collet” is illustrated as the collet 16. The collet 16 has an intake hole 16a at its substantially central portion, and it holds the semiconductor chip 3 by intaking the air inside the space formed between the recess formed at the bottom surface of the collet 16 and the main surface 3a of the semiconductor chip 3 from the intake hole 16a.

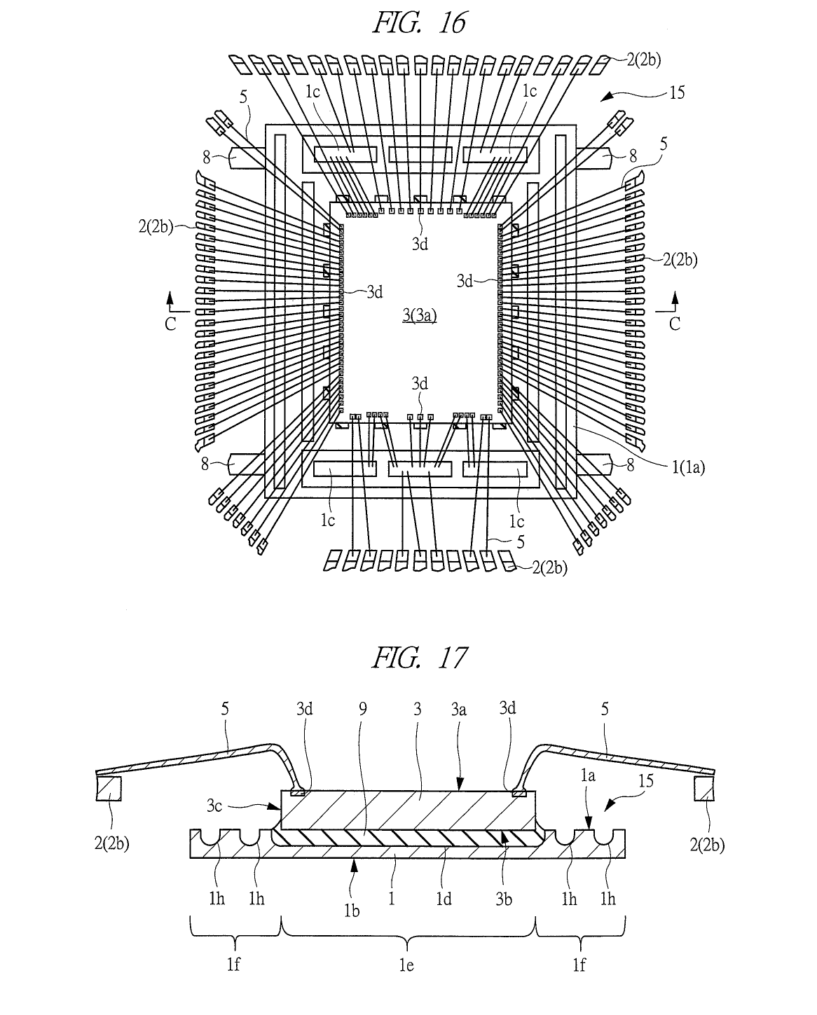

Also, since the arrangement position of the semiconductor chip 3 is determined in this process, the collet 16 not only places the semiconductor chip 3 on the adhesive 9, but also performs positioning of the semiconductor chip 3 by pressing the semiconductor chip 3 toward the die pad 1 to some extent after placing the semiconductor chip 3. Meanwhile, since the collet 16 holds the outer edge of the main surface 3a by a surface inclined to the main surface 3a of the semiconductor chip 3 as illustrated in FIG. 16, when the semiconductor chip 3 is excessively pressed by using the collet 16, defects such as cracking and chipping may occur to the semiconductor chip 3. Therefore, in this process, it is preferable to press the semiconductor chip 3 not to allow the back surface 3b of the semiconductor chip 3 to contact with the top surface 1a of the die pad 1.

Note that, in the first embodiment, space (i.e., space inside the groove portion 1d) is provided for escaping the paste-like adhesive 9 upon pressing the semiconductor chip 3 by forming the plurality of groove portions 1d to the chip-mounting region, and thus defects such as cracking and chipping are difficult to occur to the semiconductor chip 3 even if the semiconductor chip 3 is pressed by the collet 16 as compared with the case of not forming the groove portion 1d to the chip-mounting region 1e.

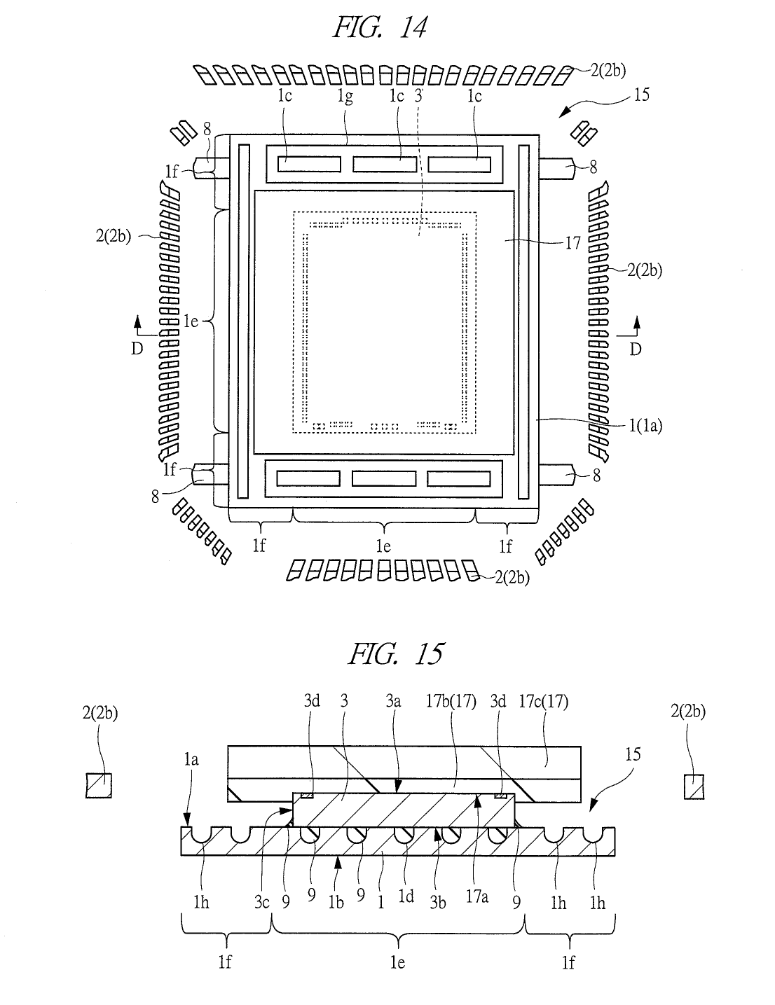

(b3) Next, as illustrated in FIGS. 14 and 15, pressure is applied from the main surface 3a of the semiconductor chip 3 with using a pressuring tool 17 to press the back surface 3b of the semiconductor chip 3 toward the top surface 1a of the die pad 1 (semiconductor chip pressuring step). FIG. 14 is an enlarged plan view illustrating a state of pressing the semiconductor chip illustrated in FIG. 12 toward the die pad, and FIG. 15 is an enlarged cross-sectional view taken along the line D-D illustrated in FIG. 14.

As illustrated in FIG. 15, the pressuring tool 17 used in this step has a main surface (third main surface) 17a abutting the main surface 3a of the semiconductor chip 3, an elastic body 17b provided to the main surface 17a, and a supporting portion 17c provided to face a surface, which the elastic body 17b has, positioned opposite to the main surface 17a.

In this process, by pressing the main surface 17 of the pressuring tool 17 downwards in FIG. 15 in the state of making the main surface 17a abut with the main surface 3a of the semiconductor chip 3, pressure is applied to the main surface 3a side of the semiconductor chip 3.

Here, in this process, the back surface 3b of the semiconductor chip 3 is pressed to come into opposing contact with the top surface 1a of the die pad 1. More specifically, the back surface 3b of the semiconductor chip 3 is pressed to contact the contact portion 1k (see FIG. 8) at the top surface 1a of the die pad 1, the contact portion 1k being provided in the chip-mounting region 1e. Therefore, when the applied pressure is biased at the main surface 3a of the semiconductor chip 3, the stress concentrates in a region to which strong pressure is applied, and thus it is concerned that defects such as cracking and chipping may occur to the semiconductor chip 3. Also, when the pressure is biased, it is concerned that the position of the semiconductor chip 3 is shifted from the chip-mounting region 1e.

Accordingly, in the first embodiment, the elastic body 17b is provided to the side of the surface opposing the main surface 17a of the pressuring tool 17. When pressure is applied to the main surface 3a of the semiconductor chip 3, reaction force of the pressure is applied to the pressuring tool 17. The elastic body 17b of the pressuring tool 17 is deformed depending on the reaction force, thereby correcting the bias of pressure and uniforming the pressure applied to the main surface 3a of the semiconductor chip 3 abutting with the main surface 17a as compared with the case of providing an inelastic material to the main surface 17a. Therefore, even when the back surface 3b of the semiconductor chip 3 is pressed to come in opposing contact with the top surface 1a of the die pad 1, occurrence of defects such as cracking and chipping of the semiconductor chip 3 can be prevented or suppressed.

In addition, in the first embodiment, the main surface 17a of the pressuring tool 17 has a wider area than the main surface 3a of the semiconductor chip 3 so that the main surface 17a of the pressuring tool 17 abuts with and covers the whole of the main surface 3a of the semiconductor chip 3. Thereby, the applied pressure can be substantially uniformed in the whole of the main surface 3a of the semiconductor chip 3. Therefore, as compared with the case of making the main surface 17a of the pressuring tool 17 abut with the main surface 3a of the semiconductor chip 3 so as to cover a part of the main surface 3a of the semiconductor chip 3, occurrence of defects such as cracking and chipping of the semiconductor chip 3 can be further surely prevented or suppressed. Also, by substantially uniforming the applied pressure in the whole of the main surface 3a of the semiconductor chip 3, position shift of the semiconductor chip 3 from the chip-mounting region 1e can be prevented or suppressed.

Further, the lead frame 15 of the first embodiment is formed such that the plurality of groove portions 1d are formed to the chip-mounting portion 1e, and the groove portions 1d are formed to extend from the inside of the chip-mounting region 1e to the chip periphery region 1f outside the outer edge of the chip-mounting region 1e in the top surface 1a of the die pad 1, as illustrated in FIG. 8. Thereby, there is a space (i.e., space inside the groove portion 1d) for escaping the paste-like adhesive 9 upon pressing the semiconductor chip 3, so that occurrence of defects such as cracking and chipping to the semiconductor chip 3 can be prevented or suppressed.

Moreover, it has been already mentioned that, by forming the groove portions 1d extending from the inside of the chip-mounting region 1e to the chip periphery region 1f in the top surface 1a of the die pad 1, the excessive paste-like adhesive 9 as being spilt from the inside of the groove portion 1d is adhered to the side surface 3c of the semiconductor chip 3.

Meanwhile, in the case of pressing the main surface 17a of the pressuring tool 17 in the state of abutting the main surface 3a of the semiconductor chip 3 so as to cover the whole of the main surface 3a of the semiconductor chip 3 as illustrated in FIG. 15, the main surface 17a of the pressuring tool 17 also covers the plurality of pads 3d formed to the main surface 3a of the semiconductor chip 3. In this process, after making the back surface 3b of the semiconductor chip 3 come into opposing contact with the top surface 1a of the die pad 1, the pressuring tool 17 is removed from the main surface 3a of the semiconductor chip 3. At this time, if the peeling property of the main surface 17a of the pressuring tool 17 to the main surface 3a of the semiconductor chip 3 (particularly, the peeling property to the exposed surface of the pad 3d) is bad, it is concerned that foreign matter may remain at the main surface 3a. When a wire bonding step as described later is carried out in the state of having the foreign matter attached on the surface of the pad 3d, it causes an electric connection failure.

Therefore, it is preferable to use a material having a high flexibility and also a good peeling property to the main surface 3a of the semiconductor chip 3 (particularly, the exposed surface of the pad 3d) for the elastic body 17b provided to the main surface 17a of the pressuring tool 17. According to the study conducted by the inventors of the present invention, resin materials such as urethane can be used as such a material. In addition, it is concerned that, as long as the pressuring tool 17 abuts with the semiconductor chip 3, when the temperature of the semiconductor chip 3 becomes excessively high, it is concerned that a part of the elastic body 17b is melted and attached to the main surface 3a of the semiconductor chip 3. Therefore, it is preferable to carry out this process at a temperature lower than a temperature at which the adhesive 9 cures.

Note that, in this process, there is a case of having the liquid component contained in the adhesive 9 exuded and spread on the top surface 1a of the die pad 1, but as the groove portion 1g is formed to surround the wire-bonding portions 1c arranged in the chip periphery region 1f in the first embodiment, the spread of the liquid component is blocked by the groove portion 1g, thereby preventing contamination of the wire-bonding portion 1c.

(b4) Next, since the adhesive 9 used in the first embodiment is a thermosetting adhesive, heat is applied after arranging the semiconductor chip 3 onto the top surface 1a of the die pad 1, thereby curing the adhesive 9 to fix the semiconductor chip 3. At this time, when the pressuring tool 17 illustrated in FIG. 15 is abutted with the main surface of the semiconductor chip 3, it is concerned that a part of the elastic body 17b is melted and attached to the main surface 3a of the semiconductor chip 3. Therefore, the pressuring tool 17 is peeled from the main surface of the semiconductor chip 3 prior to this heating step.

(c) Next, as illustrated in FIGS. 16 and 17, the plurality of pads 3d of the semiconductor chip 3 and the plurality of leads 2 are electrically connected via the plurality of wirings 5, respectively (wire-bonding step). FIG. 16 is an enlarged plan view illustrating a state of electrically connecting the pad of the semiconductor chip and the leads illustrated in FIG. 14 via wires, and FIG. 17 is an enlarged cross-sectional view taken along the line C-C illustrated in FIG. 16.

In this step, the pads 3d are electrically connected to the leads 2 (inner leads 2b) via the wires 5. Also, in the first embodiment, the another pads 3d except for those connected to the leads 2 are electrically connected to the wire-bonding portion 1c formed to the top surface 1a of the die pad 1 via the wires 5. For example, gold wires or the like can be used for the wires 5.

(d) Next, the semiconductor chip 3 and the wires 5 are sealed with a resin, thereby forming the sealing body 6 (see FIG. 7) (resin sealing step). In this step, for example, the lead frame 15 to which the wire bonding has been finished is sandwiched by molds (upper mold and lower mold; illustration thereof are omitted) having cavities formed in each unit lead frame corresponding to one piece of semiconductor device, and the sealing resin is injected inside the cavities and cured. After curing the sealing resin, as the molds are removed, the sealing body 6 (see FIG. 7) is formed in each unit lead frame corresponding to one piece of semiconductor device, and the outer leads 2a (see FIGS. 1 and 2) are led out from the side surfaces of the sealing body 6.

In this step, in view of forming the above-described third heat dissipation path, or in view of ensuring an electric connection path for supplying a reference potential or power supply potential to the die pad 1, the sealing is made with exposing the bottom surface (first back surface) of the die pad 1.

(e) Next, as illustrated in FIG. 3, the outer plating layer 7 is formed to surfaces of the die pad 1 and the leads 2 (surfaces exposed from the sealing body 6) (metal layer formation step). Note that, in this step, the plurality of unit lead frames are not singulated, and the outer leads 2a are not yet shaped into the shape illustrated in FIG. 3 (the outer leads 2a extends in the planar direction from the position of the inner leads 2b). However, since the structure other than that is the same with the structure in FIG. 3, the description will be made with reference to FIG. 3.

In this step, in the state of having the plurality of unit lead frames coupled, a metal layer of solder or the like is formed by, for example, electroplating. In this manner, the surfaces of the die pad 1 and the leads 2 exposed from the sealing body 6 are covered with the outer plating layer 7.

(f) Next, the coupled plurality of unit lead frames are singulated by decoupling each of them (singulating step). At this time, as well as cutting the tie bar 15a (see FIG. 8) coupling the plurality of outer leads 2a (see FIG. 1) and so forth, the outer leads 2a are shaped into the shape illustrated in FIG. 3, thereby obtaining the QFP 10.

### Second Embodiment

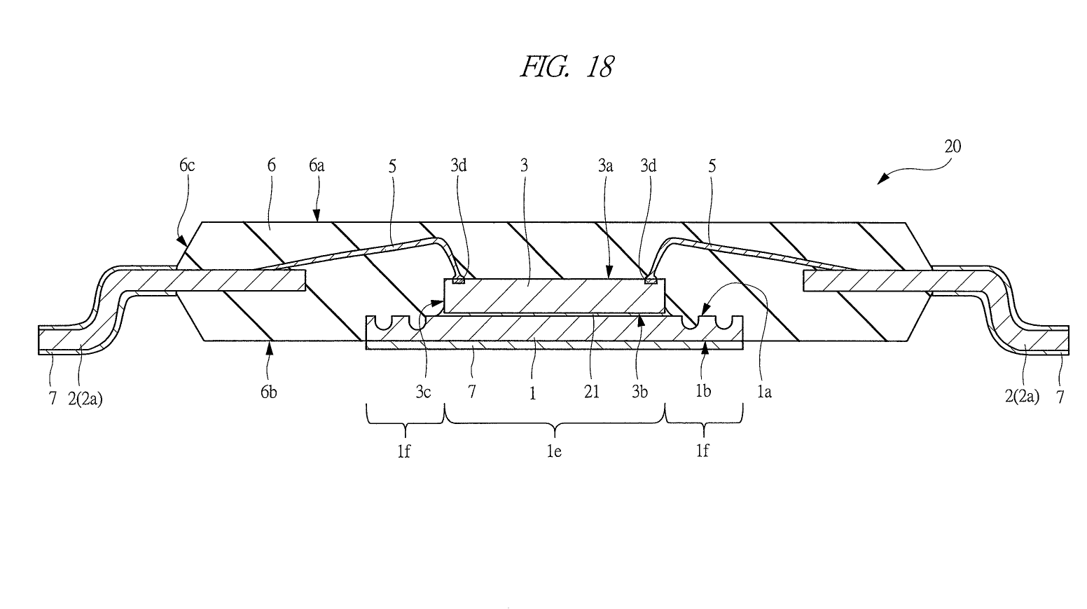

FIG. 18 is a cross-sectional view of a semiconductor device according to a second embodiment, and FIG. 19 is an enlarged cross-sectional view illustrating a periphery of an adhering portion of a die pad and a semiconductor chip illustrated in FIG. 18 in an enlarged manner. Note that, a QFP 20 according to the second embodiment has the same structure with the QFP 10 described in the first embodiment except for the different points described below. Thus, descriptions about the overlapping points with the first embodiment will be omitted.

The different points between the QFP 10 described in the first embodiment and the QFP 20 in the second embodiment are as follows. First, the QFP 20 has the top surface 1a of the die pad 1 and the back surface 3b of the semiconductor chip 3 which are not directly contacted with each other, but are fixedly adhered via an adhesive 21. Second, the adhesive 21 is made of a resin material 21a and a plurality of Ag particles (metal particles) 21b contained in the resin material 21a. Third, the die pad 1 included in the QFP 20 does not have the groove portions 1d described in FIG. 3 formed in the chip-mounting region 1e.

The QFP 20 according to the second embodiment has the top surface 1a of the die pad 1 and the back surface 3b of the semiconductor chip 3 fixedly adhered via the adhesive 21, in which a distance from the top surface 1a of the die pad 1 to the back surface 3b of the semiconductor chip 3 is made smaller than or equal to a particle diameter of the Ag particle 21b, so that the heat dissipation property is improved. More specifically, when the distance from the top surface 1a of the die pad 1 to the back surface 3b of the semiconductor chip 3 is made smaller than or equal to the particle diameter of the Ag particle 21b, each of the Ag particles 21b is made into contact with both the top surface 1a of the die pad 1 and the back surface 3b of the semiconductor chip 3, as illustrated in FIG. 19. As a result, the QFP 20 has a heat dissipation path led to the outside of the QFP 20 from the back surface 3b of the semiconductor chip 3 through the Ag particles 21b, the die pad 1, and the outer plating layer 7. Therefore, the heat transferring area becomes very large compared with the semiconductor device which dissipates heat by only the first and second heat dissipation paths described in the first embodiment, thereby improving the heat dissipation property.

However, when the heat dissipation path via the Ag particles 21b is compared with the third heat dissipation path (i.e., the heat dissipation path led out to the outside of the QFP 10 from the back surface 3b of the semiconductor chip 3 through the die pad 1 in FIG. 3) described in the first embodiment, the above-described third heat dissipation path has higher heat dissipation property. This may be because, in the second embodiment, while there is a limitation in increasing the cross-sectional area of each of the heat dissipation paths because the cross-sectional area of individual Ag particle 21b is small, the third heat dissipation path can have the wide cross-sectional area of each of the heat dissipation paths depending on the arrangement of the groove portions 1d. Therefore, in the point of view of improvement in heat dissipation property, the QFP 10 described in the first embodiment is more preferable.

Here, the particle diameter of the Ag particle 21b will be explained. The shape and size of the Ag particles 21b may not necessarily be constant as illustrated in FIG. 19, for example. In the second embodiment, each of the Ag particles 21b is contacted with both the top surface 1a of the die pad 1 and the back surface 3b of the semiconductor chip 3 so that the heat dissipation path to the die pad 1 is ensured. Therefore, from this point of view, the distance from the top surface 1a of the die pad 1 to the back surface 3b of the semiconductor chip 3 is necessary to be smaller than or equal to the biggest particle diameter of the particle diameters of the plurality of Ag particles 21b. Also, as for the Ag particle 21b having a flattened shape instead of a spherical shape, the distance is necessary to be smaller than or equal to the longest diameter.

More specifically, when each of the plurality of Ag particles 21b has a different particle diameter, the distance from the top surface 1a of the die pad 1 to the back surface 3b of the semiconductor chip 3 is particularly preferable to be smaller than or equal to an average particle diameter of the plurality of Ag particles 21b (an average value of the longest diameters of the respective Ag particles 21b). The Ag particles 21b mostly have a flattened shape as illustrated in FIG. 19, and the Ag particle 21b having such a shape is inclined when the semiconductor chip 3 is pressed toward the die pad 1, thereby obtaining the distance smaller than or equal to the average particle diameter of the plurality of Ag particles 21b.

However, in the case where the Ag particle 21b having a specifically-large particle diameter is mixed in the adhesive 21, the Ag particle 21b having a specifically-large particle diameter becomes a constraint in shortening the distance from the top surface 1a of the die pad 1 to the back surface 3b of the semiconductor chip 3. Therefore, it is preferable to previously classify the Ag particles 21b to uniform the sizes to some extent. This classifying processing is preferable to be performed prior to diffusing the Ag particles 21b in the paste-like resin material 21a in the preparing step of the paste of the adhesive 21.

By performing the classifying processing, the sizes of the Ag particles 21b can be uniformed to some extent, and thus each of the plurality of Ag particles 21b can be contacted with both the top surface 1a of the die pad 1 and the back surface 3b of the semiconductor chip 3.

Meanwhile, the adhesive 21 is an adhesive made by diffusing the plurality of Ag particles (metal particles) 21b in the resin material 21a, and an adhesive for die bonding which is called Ag paste is also known as a material containing Ag particles in a resin material.

However, generally, when fixedly adhering a semiconductor chip to a die pad via an Ag paste, a distance from the back surface of the semiconductor chip to the top surface of the die pad is about 30 μm. On the other hand, the particle diameter of the Ag particle 21b is about 5 μm, or 10 μm or smaller for a particularly-large one. Therefore, there is no effort to improve the heat dissipation property by making each of the plurality of Ag particles 21b contact with both the top surface 1a of the die pad 1 and the back surface 3b of the semiconductor chip 3 in the manner of the second embodiment. Such a reason to this is considered that breakage of the semiconductor chip 3 is concerned while the semiconductor chip 3 is necessary to be pressed by strong pressure to make the distance from the top surface 1a of the die pad 1 to the back surface 3b of the semiconductor chip 3 smaller than or equal to the particle diameter of the Ag particle 21b, and no detailed study about it has been made.

On the other hand, as described in the first embodiment above, the inventors of the present invention have found out a technique of performing the above-described semiconductor chip pressing step in the die bonding step, thereby preventing breakage of the semiconductor chip 3 and also pressing the semiconductor chip 3 toward the die pad 1 by strong pressure. That is, in the second embodiment, by pressing the semiconductor chip 3 such that the distance from the top surface 1a of the die pad 1 to the back surface 3b of the semiconductor chip 3 becomes smaller than or equal to the particle diameters of the plurality of Ag particles 21b, each of the plurality of Ag particles 21b can be contacted with both the top surface 1a of the die pad 1 and the back surface 3b of the semiconductor chip 3. As a result, the heat dissipation property of the QFP 20 can be improved.

While the structure in which the groove portion 1d described with reference to FIG. 3 is not formed in the chip-mounting region 1e has been described in the second embodiment, as a modification example of the QFP 20, the groove portion 1d described in the first embodiment can be formed to the top surface 1a of the die pad 1 of the QFP 20. In this case, since there is a space for escaping the paste-like adhesive 21 upon pressing the semiconductor chip 3 (i.e., space in the groove portion 1d), breakage of the semiconductor chip 3 can be further surely prevented.

### Third Embodiment

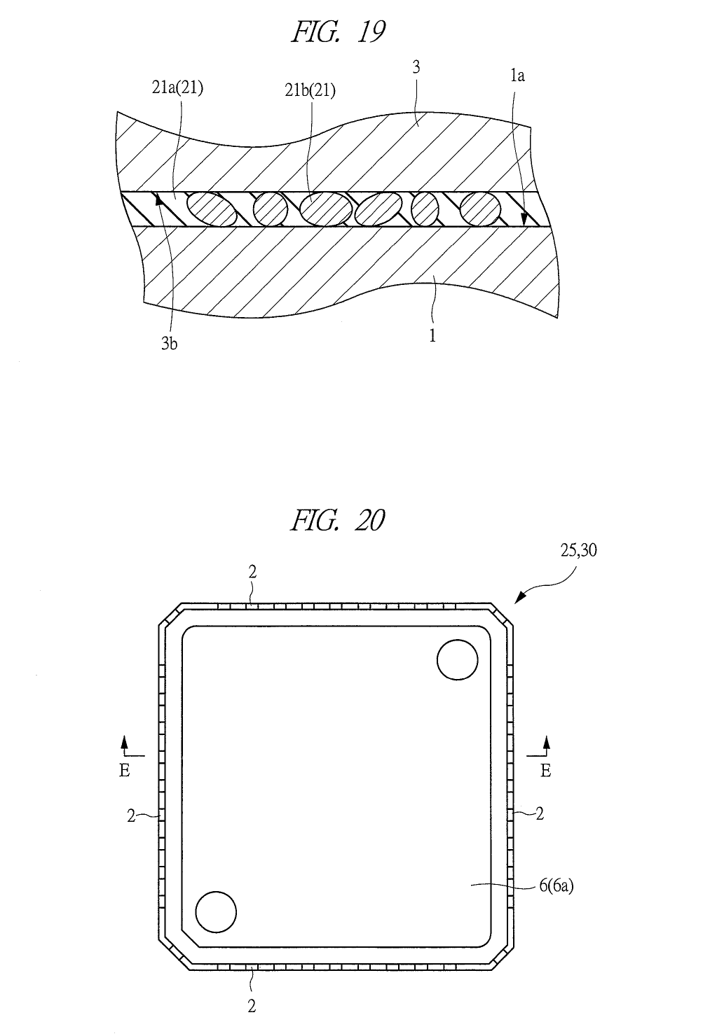

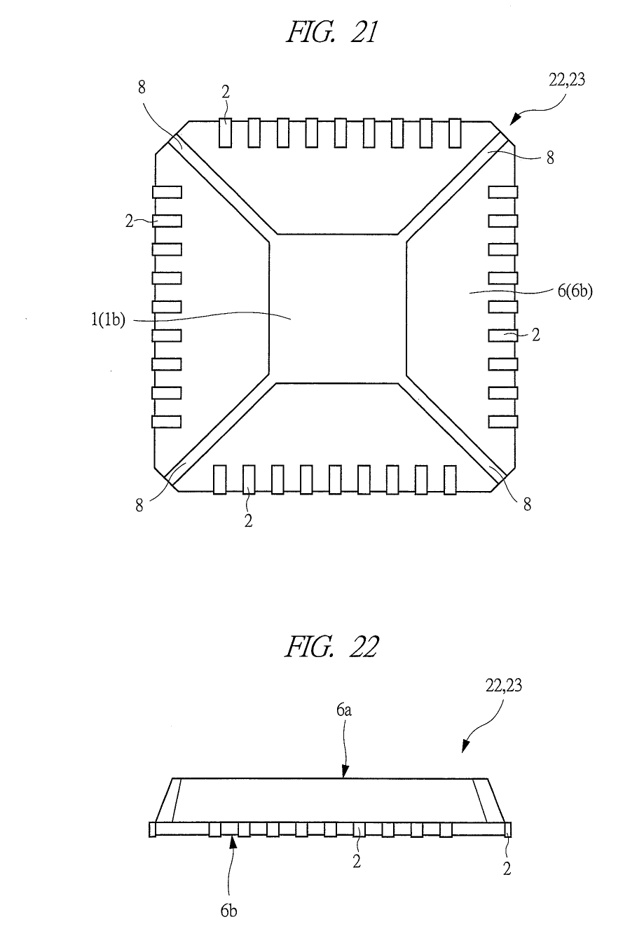

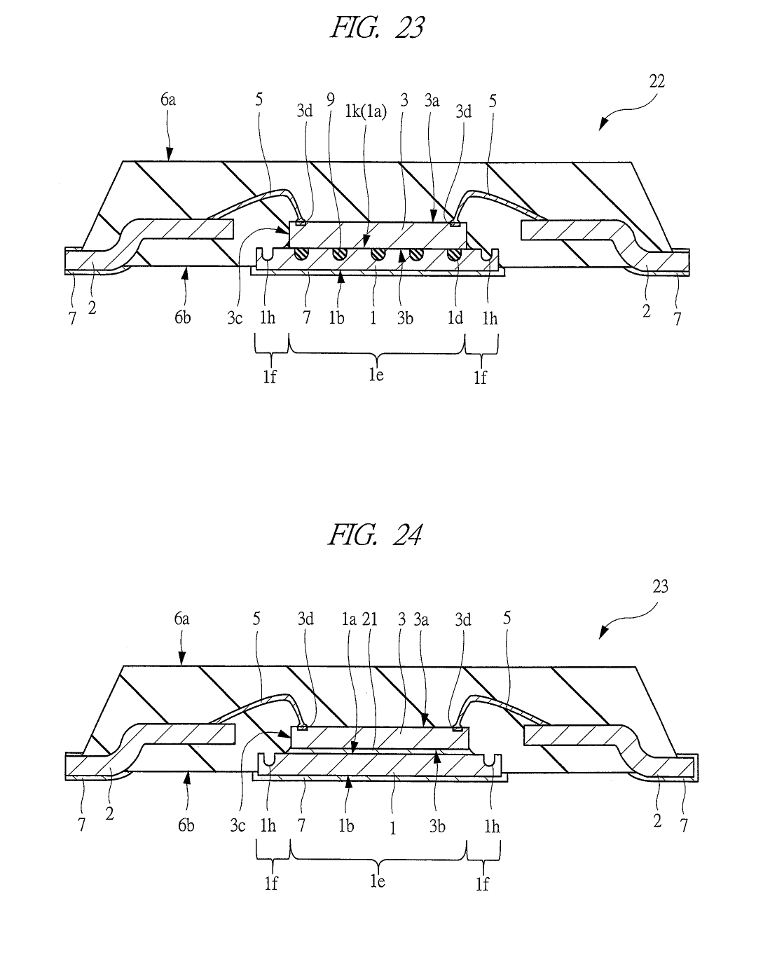

While the QFPs 10 and 20 have been described as examples of the semiconductor devices in the first and second embodiments described above, a case of using a QFN (quad flat non-leaded package) will be described in a third embodiment. FIGS. 20, 21, and 22 are a top view, a bottom view, and a side view of a semiconductor device according to the third embodiment, respectively. And, each of FIGS. 23 and 24 is a cross-sectional view taken along the line E-E illustrated in FIG. 20.

Note that a QFN 23 illustrated in FIG. 24 is a QFN that is a modification example with respect to a QFN 22 illustrated in FIG. 23, and connection structures of the semiconductor chip 3 and the die pad 1 in the QFNs 22 and 23 correspond to QFPs 10 and 20, respectively.

Different points between the QFPs 10 and 20 in the first and second embodiments described above and the QFNs 22 and 23 in the third embodiment are as follows. That is, the QFNs 22 and 23 have the plurality of leads 2, which are external connection terminals, exposed from the bottom surface 6b side of the sealing body 6, and do not have the outer leads 2a (see FIG. 1) being formed extending long from the side surface of the sealing body 6 like the QFPs 10 and 20.

The QFNs 22 and 23 do not have the outer leads 2a (see FIG. 1) formed extending long from the side surface of the sealing body 6, and the plurality of leads 2 are exposed from the bottom surface 6b side of the sealing body 6, thereby minimizing the mounting area for mounting them on the mounted board.

Here, since the QFNs 22 and 23 do not have the outer leads 2a (see FIG. 1) formed extending long from the side surface of the sealing body 6, the heat dissipation efficiency of the heat dissipation path through the lead 2 is lower in the QFNs 22 and 23 as compared with the QFP. Accordingly, it is particularly effective in the point of view of improving the heat dissipation property to form the third heat dissipation path through the die pad 1 like the QFNs 22 and 23.

More specifically, in the same manner as the QFP 10 in the first embodiment described above, in the QFN 22 illustrated in FIG. 23, the plurality of groove portions (first groove portions) 1d are formed in the chip-mounting region of the top surface 1a of the die pad 1, and the adhesive 9 is buried in the groove portions 1d, so that the back surface 3b of the semiconductor chip 3 and the top surface 1a of the die pad 1 can be in opposing contact with each other. Consequently, the heat transferring area between the back surface 3b of the semiconductor chip 3 and the top surface 1a of the die pad 1 can be large, thereby improving the heat dissipation property.

Also, in the QFN 23 illustrated in FIG. 24, in the same manner as the QFP 20 in the second embodiment described above, while the top surface 1a of the die pad 1 and the back surface 3b of the semiconductor chip 3 are fixedly adhered via the adhesive 21, the distance from the top surface 1a of the die pad 1 to the back surface 3b of the semiconductor chip 3 is made smaller than or equal to the particle diameter of the Ag particle 21b contained in the adhesive 21, thereby improving the heat dissipation property.

Further, in the QFNs 22 and 23, the suspending lead 8 is exposed from the bottom surface 6b side of the sealing body 6 as illustrated in FIG. 21. In this manner, the area of the metal parts exposed to the outside of the semiconductor device can be increased, thereby further improving the heat dissipation property.

Note that, while the modification examples of the QFPs 10 and 20 described in the first and second embodiments can be employed also in the QFNs 22 and 23 according to the third embodiment, overlapped descriptions will be omitted.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, while the QFPs 10 and 20, and the QFNs 22 and 23 have been exemplified as the semiconductor devices in the first, second, and third embodiments, the package structures of the semiconductor devices are not limited to the QFP in which leads are arranged along the four sides composing the outer circumference of the semiconductor device. For example, the structure can be used for an SOP (small outline package) or an SON (small outline non-leaded package) in which a plurality of leads are arranged to only two sides opposing each other among the four sides of the rectangle which the bottom surface of the semiconductor device has.

Also, for example, while the structure in which the suspending lead 8 is exposed from the bottom surface 6b side of the sealing body 6 is described in the third embodiment, the structure can be also employed to the QFPs 10 and 20 described in the first and second embodiments. In this case, the heat dissipation property can be further improved.

The present invention can be used for a resin-sealed semiconductor device mounting a semiconductor chip on a die pad which a lead frame has and having the semiconductor chip sealed by a sealing body.

What is claimed is:

1. A semiconductor device comprising:
a chip-mounting portion having a first main surface, and a first back surface positioned opposite to the first main surface;
a plurality of suspending leads supporting the chip-mounting portion;
a plurality of leads arranged around the chip-mounting portion;
a semiconductor chip having a second main surface, a second back surface positioned opposite to the second main surface, and a plurality of pads formed to the second main surface, the semiconductor chip being fixedly adhered onto the first main surface so as to have the second back surface being in opposing contact with the first main surface of the chip-mounting portion;
a plurality of wires electrically connecting the plurality of pads of the semiconductor chip and the plurality of leads, respectively; and
a sealing body sealing the semiconductor chip and the plurality of wires, wherein
a plurality of first groove portions are formed to a first region opposing the second back surface of the semiconductor chip in the first main surface of the chip-mounting portion, and
an adhesive for fixedly adhering the semiconductor chip onto the first main surface of the chip-mounting portion is formed inside the plurality of first groove portions.

2. The semiconductor device according to claim 1, wherein
the first back surface of the chip-mounting portion is exposed from the sealing body.

3. The semiconductor device according to claim 2, wherein
an area of the first main surface of the chip-mounting portion is larger than or equal to an area of the second back surface of the semiconductor chip.

4. The semiconductor device according to claim 3, wherein
the plurality of first groove portions in the first main surface of the chip-mounting portion are formed to extend from the inside of the first region opposing the second back surface of the semiconductor chip to a second region outside an outer edge of the first region.

5. The semiconductor device according to claim 4, wherein
the adhesive is arranged to extend from the inside of the first groove portion to a side surface of the semiconductor chip, and is adhered to the second back surface and the side surface of the semiconductor chip.

6. The semiconductor device according to claim 1, wherein
a second groove is formed in a second region arranged outside the outer edge of the first region in the first main surface of the chip-mounting portion, and the sealing body is buried in the second groove portion.

7. A semiconductor device comprising:
a chip-mounting portion having a first main surface, and a first back surface positioned opposite to the first main surface;
a plurality of suspending leads supporting the chip-mounting portion;
a plurality of leads arranged around the chip-mounting portion;
a semiconductor chip having a second main surface, a second back surface positioned opposite to the second main surface, and a plurality of pads formed to the second main surface, the semiconductor chip being fixedly adhered onto the first main surface via an adhesive so as to have the second back surface opposing the first main surface of the chip-mounting portion;
a plurality of wires electrically connecting the plurality of pads of the semiconductor chip and the plurality of leads, respectively; and
a sealing body sealing the semiconductor chip and the plurality of wires, wherein
the adhesive is formed of a resin material and a plurality of metal particles contained in the resin material, and
a distance from the first main surface of the chip-mounting portion to the second back surface of the semiconductor chip is smaller than or equal to a particle diameter of the plurality of metal particles.

8. The semiconductor device according to claim 7, wherein
the first back surface of the chip-mounting portion is exposed from the sealing body.

9. The semiconductor device according to claim 8, wherein
a plurality of first groove portions are formed to a region opposing the second back surface of the semiconductor chip in the first main surface of the chip-mounting portion, and
an adhesive for fixedly adhering the semiconductor chip onto the first main surface of the chip-mounting portion is formed inside the plurality of first groove portions.

10. The semiconductor device according to claim 9, wherein
an area of the first main surface of the chip-mounting portion is larger than an area of the second back surface of the semiconductor chip,
the plurality of first groove portions in the first main surface of the chip-mounting portion are formed to extend from the inside of the first region opposing the second back surface of the semiconductor chip to a second region outside an outer edge of the first region, and
the adhesive is arranged to extend from the inside of the first groove portion to a side surface of the semiconductor chip, and is adhered to the side surface of the semiconductor chip.

11. A method of manufacturing a semiconductor device, comprising the steps of:
(a) preparing a lead frame having: a chip-mounting portion having a first main surface and a first back surface opposite to the first main surface; a plurality of suspending leads supporting the chip-mounting portion; a plurality of leads arranged around the chip-mounting portion; and a frame body formed integrally with the plurality of suspending leads and the plurality of leads;
(b) mounting a semiconductor chip having a second main surface, a second back surface opposite to the second main surface, and a plurality of pads formed to the second main surface onto the first main surface of the chip-mounting portion so as to have the second back surface opposing the first main surface of the chip-mounting portion;
(c) electrically connecting the plurality of pads of the semiconductor chip and the plurality of leads via a plurality of wires, respectively; and
(d) sealing the semiconductor chip and the plurality of wires by a resin to form a sealing body, wherein
the step (b) further includes the steps of:
(b1) applying an adhesive to the chip-mounting portion;
(b2) arranging the semiconductor chip onto the chip-mounting portion to which the adhesive is applied; and
(b3) pressing the second back surface of the semiconductor chip toward the first main surface of the chip-mounting portion by applying pressure from the second main surface side of the semiconductor chip with using a pressuring tool having a third main surface to be abutted on the second main surface of the semiconductor chip.

12. The method of manufacturing a semiconductor device according to claim 11, wherein,
in the step (d), the sealing is made so as to have the first back surface of the chip-mounting portion exposed from the resin.

13. The method of manufacturing a semiconductor device according to claim 12, wherein
a plurality of first groove portions are formed in a region opposing the second back surface of the semiconductor chip in the first main surface of the chip-mounting portion of the lead frame prepared in the step (a),
the plurality of first groove portions are formed in the first main surface of the chip-mounting portion to extend from the inside of a first region opposing the second back surface of the semiconductor chip to a second region outside an outer edge of the first region, and,
in the step (b3), the second main surface of the semiconductor chip is pressed such that the second back surface comes into opposing contact with the first main surface of the chip-mounting portion.

14. The method of manufacturing a semiconductor device according to claim 13, wherein
a second groove portion is formed in the second region of the chip-mounting portion of the lead frame prepared in the step (a), and
the first groove portion and the second groove portion are simultaneously formed by etching.

15. The method of manufacturing a semiconductor device according to claim 11, wherein
an elastic body is arranged to the third surface of the pressuring tool.

16. The method of manufacturing a semiconductor device according to claim 11, wherein
the third main surface of the pressuring tool has a larger area than that of the second main surface of the semiconductor chip, and,
in the step (b3), the third main surface of the pressuring tool is abutted on the second main surface of the semiconductor chip so as to cover the whole second main surface of the semiconductor chip.

17. The method of manufacturing a semiconductor device according to claim 11, wherein
the adhesive is formed of a resin material and a plurality of metal particles contained in the resin material, and,
in the step (b3), the second back surface of the semiconductor chip is pressed such that a distance from the first main surface of the chip-mounting portion to the second back surface of the semiconductor chip becomes smaller than or equal to a particle diameter of the plurality of metal particles.
